(19) United States
(12) Patent Application Publication
(10) Pub. No.: US 2007/0114647 A1
(43) Pub. Date: May 24, 2007

(54) Carrier board structure with semiconductor chip embedded therein

(76) Inventor: Shih-Ping Hsu, Hsin-chu (TW)

Correspondence Address: Mr. Joseph A. Sawyer, Jr.;SAWYER LAW GROUP LLP, Suite 406, 2465 East Bayshore Road, Palo Alto, CA, 94303, US

(21) Appl. No.: 11/471,424

(22) Filed: Jun. 20, 2006

(30) Foreign Application Priority Data
Nov. 23, 2005 (TW) 094141071

(51) Int. Cl. H01L 23/02; H01L 21/00

(52) U.S. Cl. 257/679; 438/121; 257/E23.064

(57) ABSTRACT

A carrier board structure with a semiconductor chip embedded therein is provided, which includes a carrier board having a first surface with at least one opening and a second surface. Allowing a semiconductor chip to be embedded in the opening in a manner that the active surface of the semiconductor chip is slightly lower than the first surface of carrier board. An adhesive material is used to fill in the gap between the carrier board and the semiconductor chip, and to cover a part of the active surface of the semiconductor chip for fixing the semiconductor chip in the opening. As the adhesive material is used to surround the periphery of the semiconductor chip, and the gap between the semiconductor chip and the carrier board can completely filled with the adhesive material without formation of voids therein, the semiconductor chip can be free from cracking issue. Further, the popcorn effect of the carrier board can be prevented form occurrence.

### CROSS-REFERENCE TO RELATED APPLICATION

This application claims benefit under 35 USC 119 to Taiwan Application No. 094141071, filed Nov. 23, 2005.

### FIELD OF THE INVENTION

The present invention relates to carrier board structures for semiconductor chips embedded therein, and more particularly, to a circuit board structure with a semiconductor chip embedded therein.

### BACKGROUND OF THE INVENTION

As integration of electronic devices advances dramatically, the technology of embedding a semiconductor chip within the carrier board has gradually gained in popularity. The semiconductor chip embedded therein can be an active component or a passive component.

Referring to FIG. 1, a schematic cross-sectional view of a conventional substrate with a semiconductor chip embedded therein is shown. The substrate 10 is formed with at least one opening 100 on the upper surface thereof, for accommodating a semiconductor chip 11. The semiconductor chip 11 has an active surface 11a having a plurality of electrode pads 112 mounted on the upper surface of the substrate 10 in such a way that the active surface 11a of the semiconductor chip 11 is flush with the upper surface of the substrate 10. A dielectric layer 12 having a circuit layer 13 thereon is

formed on the active surface 11a of the semiconductor chip 11. The circuit layer 13 has a plurality of conductive vias 131 for electrically connecting with the electrode pads 112 of the semiconductor chip. Following this method, a multi-layered circuit board is formed by this build-up method to form multiple circuit layers and dielectric layers sequentially.

However, in practice, it is considerably difficult to align the active surface 11a of a semiconductor chip 11 flush with the surface of the substrate, resulting in the active surface 11a of the semiconductor chip 11 being either lower or higher than the surface of substrate. As such, planarity of the overall structure might be insufficient, thereby hindering the formation of the dielectric layer between a surface of substrate 10 and an active surface 11a of a semiconductor chip 11.

The technology of embedding a semiconductor chip in a build-up substrate structure and the method thereof are disclosed in U.S. Pat. No. 6,734,534 as shown in FIGS. 2A and 2B. Referring to FIG. 2A, a circuit board 20 having a first surface 20a and a second surface 20b is formed with a plurality of openings 201 penetrating through the first surface 20a and the second surface 20b. A semiconductor chip 22 is embedded in the opening 201. The semiconductor chip 22 has an active surface 22a with a plurality of electrode pads 221 formed thereon, and a protective film layer 23 is formed over the first surface 20a of the circuit board and the active surface 22a of the semiconductor chip 22. The opening 201 is filled with an encapsulation material for fixing the semiconductor chip 22 within the opening 201.

Referring to FIG. 2B (which inverts the orientation relative to FIG. 2A), the protective film layer 23 is then removed, so as to insure co-planarity between the active surface 22a of the semiconductor chip 22 and the first surface 20a of circuit board 20. Then, a dielectric layer 25 and a circuit layer 24 are formed on the first surface 20a of the circuit board 20 and the active surface 22a of the semiconductor chip 22. The circuit layer has a plurality of conductive vias 24a for establishing electrical connections with the electrode pads 221 of the semiconductor chip 22.

Accordingly, when embedding the conventional semiconductor chip in a circuit board, it is desirable to align the active surface 22a of a semiconductor chip 22 flush with the first surface 20a of a circuit board 20. However, it is very difficult to establish complete co-planarity in practice. Although U.S. Pat. No. 6,734,534 discloses a method for making the active surface 22a of the semiconductor chip 22 to be flush with the first surface 20a of the circuit board 20 through forming a protective film layer 23, the protective film layer 23 is a flexible substance, and, in that the semiconductor chip 22 is embedded and fixed in position within the opening 201 of the circuit board 20, the active surface 22a of semiconductor chip may protrude into the flexible protective film 23. Therefore, as the semiconductor chip is not really evenly adhered to the surface of the protective film 23, after removing the protective film 23, the active surface 22a of the semiconductor chip might either protrude or be recessed, making it difficult to achieve sufficient co-planarity between the active surface 22a of the semiconductor chip 22 and the first surface 20a of a circuit board 20.

Furthermore, since the coefficient of thermal expansion (CTE) of the active surface, encapsulation material, and substrate surface are very different, thermal stress easily occurs, which might cause the semiconductor chip to crack during high temperature processing or reliability testing.

Moreover, even when the active surface is flush with the surface of the substrate, another drawback is that it is more difficult to fill adhesive material in the gap between a semiconductor chip and a substrate. If the encapsulation material in the opening 201 protrudes, the semiconductor chip might suffer from cracking under the pressure. In contrast, if the encapsulation material 24 in the opening 201 is recessed, the semiconductor chip might suffer from formation of voids at the periphery of the semiconductor chip during high temperature processing and reliability testing.

Therefore, there is a need to develop a way to more evenly embed a semiconductor chip in a substrate or carrier board, as well as to solve the foregoing conventional problems.

### SUMMARY OF THE INVENTION

In the view of the prior art drawbacks, a primary objective of the present invention is to provide a carrier board structure with a semiconductor chip embedded therein, which is formed in a relatively easier fabricating process.

Another objective of the invention is to provide a carrier board structure with a semiconductor chip embedded therein, for preventing damages of the semiconductor chip due to thermal stress.

Still another objective of the invention is to provide a carrier board structure with a semiconductor chip embedded therein, in which the semiconductor chip is surrounded by materials with the same thermal expansion coefficient so as to improve reliability of the product.

In order to achieve the foregoing and other objectives, the present invention discloses a carrier board structure with a semiconductor chip embedded therein, comprising: carrier board having a first surface and an opposing second surface, in which the first surface is formed with an opening; semiconductor chip having an active surface and an opposing inactive surface which is embedded within the opening and positioned lower than the first surface of the carrier board; adhesive material filling the gap between the carrier board and the semiconductor chip, and covering a part of the active surface of the semiconductor chip, so as to fix the semiconductor chip within the opening.

As mentioned above, a carrier board is a metal board, a ceramics board, an insulating board or an organic circuit board, or a foregoing build-up structure. The opening can be in the form of a through opening penetrating the first surface and the second surface or an opening formed on the first surface. The semiconductor chip can be an active component or passive component, and has electrode pads on the active surface for connecting with conductive vias. In addition, the adhesive material can be plastic material, resin, epoxy compound or a synthetic rubber.

The carrier board structure further comprises a circuit build-up structure formed on the first surface of the carrier board and the active surface of the semiconductor chip. The circuit build-up structure comprises a dielectric layer, circuit layer formed on the dielectric layer and conductive vias formed within the dielectric layer and electrically connected to the electrodes of the semiconductor chip. Moreover, on the surface of the circuit build-up structure, electrical connections and an insulating layer similar to a solder mask having a plurality of openings for exposing the electrical connections are formed thereon.

In comparison with the prior art which is difficult to achieve satisfactory co-planarity between the active surface of the semiconductor chip and the surface of the carrier board, the present invention proposes a carrier board structure with semiconductor chip embedded therein, in which the semiconductor chip is slightly lower than the first surface of the carrier board, such that the fabricating process is simplified, and the requirement for co-planarity is eliminated.

Since the active surface of the semiconductor chip is slightly lower than the first surface of the carrier board, it can be ensured that the opening of the carrier board is completely filled with the adhesive material so as to fix the semiconductor chip therein. Moreover, thermal stress generated due to heat treatment causing cracking of the semiconductor chip can be avoided, thereby improving reliability of the product.

Moreover, when the adhesive material overflows, it naturally covers a part of the active surface of the semiconductor chip, allowing the periphery of the semiconductor chip to be surrounded by a material with the same thermal expansion coefficient, so as to make the whole structure more stable and reliable.

In summary, a carrier board structure with a semiconductor chip embedded therein proposed by the present invention, solves the drawbacks such as damages of semiconductor chip and popcorn effect of the circuit board in a conventional circuit board with an embedded semiconductor chip and thereby improving the reliability of the product as well as simplifying the fabricating process.

### BRIEF DESCRIPTION OF THE DRAWINGS

FIG. 1 (PRIOR ART) is a schematic cross-sectional diagram of a conventional substrate structure with a semiconductor chip embedded therein.

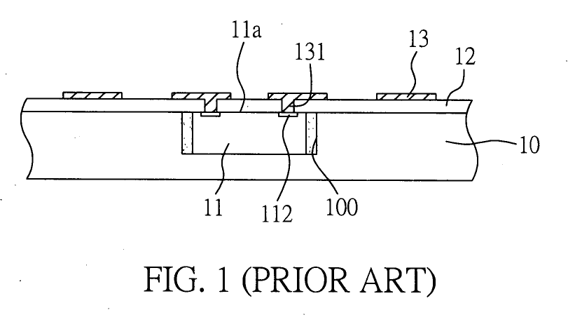

FIGS. 2A and 2B (PRIOR ART) are cross-sectional views of substrate structure with a semiconductor chip embedded therein disclosed in U.S. Pat. No. 673,453,4.

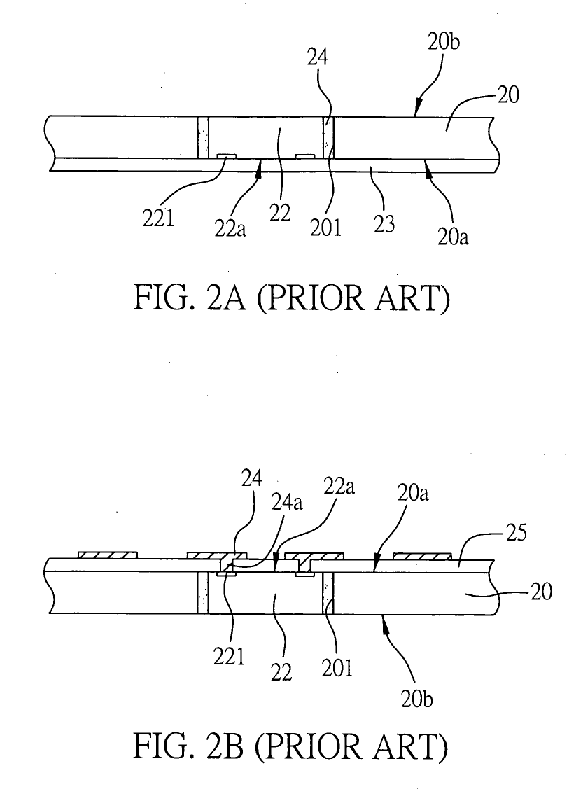

FIGS. 3A and 3B are the schematic cross-sectional diagrams of a carrier board structure with a semiconductor chip embedded therein of the first preferred embodiment of the present invention.

FIG. 4 is a schematic cross-sectional diagram of a circuit build-up structure of circuit layer of the carrier board structure with a semiconductor chip embedded therein of the present invention.

### DETAILED DESCRIPTION OF THE PREFERRED EMBODIMENTS

The present invention is described in the following with specific embodiments, so that one skilled in the pertinent art can easily understand other advantages and effects of the present invention from the disclosure of the invention. The present invention may also be implemented and applied according to other embodiments, and the details may be modified based on different views and applications without departing from the spirit of the invention. In addition, the drawing and the devices shown herein are not to scale and are made in simplicity with provision of only associated devices related to the invention; in practical usage, the device should be more complexly structured and the number, size, shape and arrangement of each device can be varied accordingly.

### First Preferred Embodiment

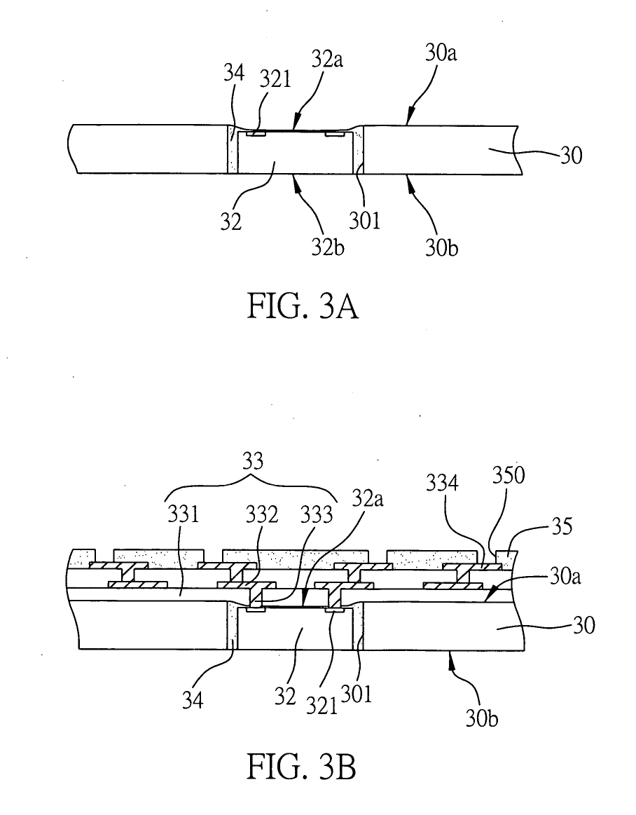

Referred to FIG. 3A is a schematic cross-sectional diagram of a carrier board structure with a semiconductor chip embedded therein of the first preferred embodiment of the present invention. As shown in the drawing, the circuit board structure at least comprises: a carrier board 30 having a first surface 30a and an opposing second surface 30b formed with at least one opening 301 penetrating through the first surface 30a and the second surface 30b ; at least one semiconductor chip 32 having an active surface 32a and an opposing inactive surface 32b, embedded in the opening 301 in such a manner that the active surface 32a thereof is slightly lower than the first surface 30a of carrier board 30; an adhesive material 34 filling the gap between the carrier board 30 and the semiconductor chip 32, and covering a part of the active surface 32a of the semiconductor chip 32 for fixing the semiconductor chip 32 in the opening 301. The above-mentioned covered part is preferably on the electrode pads 321 of the semiconductor chip 32, so as to avoid the electrode pads being oxidized.

The carrier board 30 is a metal board, a ceramics board, an insulating board or an organic circuit board. When the carrier board 30 is an organic circuit board, it can be used as printing circuit board or IC packaging substrate. The semiconductor chip 32 can be an active component, such as CPU, ASIC or DRAM, SRAM, SDRAM etc, or a passive component such as capacitors, resistor, or inductors. The active surface 32a of the semiconductor chip 32 has a plurality of electrode pads. The adhesive material 34 can be plastic material, resin, epoxy compound or synthetic rubber.

Referring to FIG. 3B, the carrier board structure with an embedded semiconductor chip proposed by the invention further comprises a circuit build-up structure 33 on the first surface 30a of a carrier board 30 and the active surface 32a of a semiconductor chip 32. The circuit build-up structure 33 comprises: at least one dielectric layer 331; circuit layer 332 formed on the dielectric layer 311; and conductive vias 333 formed within the dielectric layer 331 and electrically connected to the electrode pad 321 of the semiconductor chip 32. In addition, the electrical connection pads 334 are formed in the outermost circuit layer of the circuit build-up structure 33 and an insulating layer 35 such as solder mask is formed to cover the circuit build-up structure 33 and has a plurality of openings 350 for exposing the electrical connection pads 334 of the circuit build-up structure. It is also applicable to mount conductive elements such as solder balls on the electrical connection pads (not shown in the drawing). It should be noted, the material of the dielectric layer 331, which has contact with the active surface 32a of the semiconductor chip 32, can be the same of different from the adhesive material.

Regarding to quite a large number of various methods for forming circuit build-up structure, since they are all well known, thus are not described herein. However it should be noted, the circuit build-up structure applied in a carrier board structure with an embedded semiconductor chip should not be limited by the present embodiment, but on the contrary any modification within the scope of invention should be included in the present invention and can be implemented according to practical needs.

### Second Preferred Embodiment

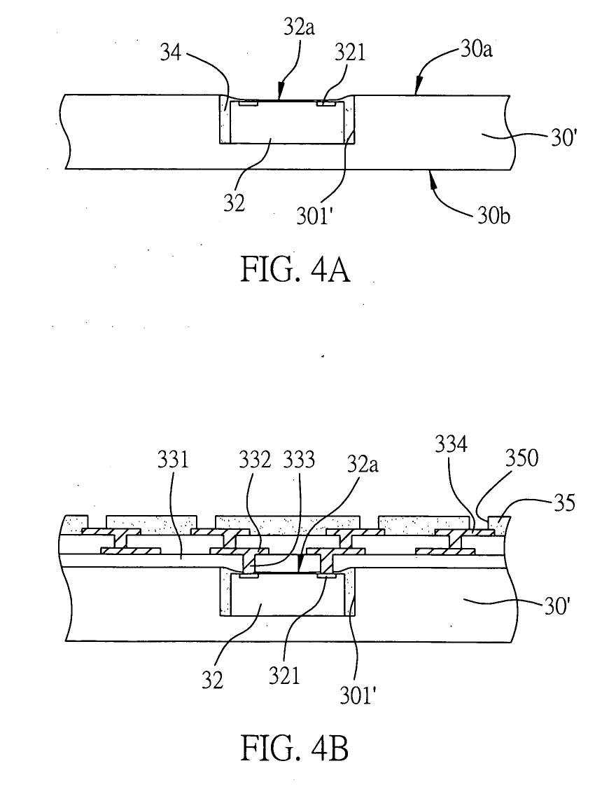

Refer to FIGS. 4A and 4B are schematic cross-sectional diagrams showing a carrier board structure with an embedded semiconductor chip of another preferred embodiment of the present invention. The difference with the first embodiment is that in this embodiment the opening 301 of the carrier board 30′ is not a through hole penetrating through the first surface 30a and the second surface 30b, but instead it is a dent penetrating only through the first surface 30a which is used to embed the semiconductor chip 32. The active surface 32a of the semiconductor chip 32 is lower than the first surface 30a of the carrier board 30′, an the gap between the carrier board 30′ and the semiconductor chip 32 is filled with an adhesive material 34, for fixing the semiconductor chip 32 in place. The adhesive material 34 covers part of the active surface 32a of the semiconductor chip 32. Moreover, on the first surface 30a of the carrier board 30′ and the active surface 32a of the semiconductor chip 32, there is formed with a circuit build-up structure 33, on which an insulating layer 35 is formed for protecting the circuits underneath.

Accordingly, the active surface of the semiconductor chip is slightly lower than the first surface of carrier board which is embedded in the opening, such that the prior art drawback of prolonged operation hours and the requirement of high précised technology to make satisfactory co-planarity between the active surface of the semiconductor chip and the first surface of the carrier board can be solved, so as to increase the final yield.

Moreover, when the active surface of the semiconductor chip is coplanar with the first surface of the carrier board, since the active surface of the semiconductor chip, the adhesive material, the first surface of the carrier board are on the same planarity and each has different thermal expansion coefficient, it is easy to generate thermal stress during high temperature process and reliability test, leading to crack of semiconductor chip. The carrier board structure with embedded semiconductor chip proposed by the invention allows the active surface of a semiconductor chip to be slightly lower than the first surface of a carrier board, so as to effectively reduce the thermal stress, as well as to avoid damage of semiconductor chip caused by different thermal expansion coefficient.

Additionally, when the active surface of the semiconductor chip is coplanar with the first surface of the carrier board in prior art, another drawback is that it is more difficult to control the amount of adhesive to be filled in the gap between the semiconductor chip and the carrier board. If the encapsulation material in the opening protrude, it is easy for the semiconductor chip to suffer from cracking under the pressure, and if the encapsulation material in the opening is dented, it is easy for the semiconductor chip to suffer from the formation of voids at the periphery of the semiconductor chip during latter high temperature processing or reliability testing, thus leading to the popcorn effect of the carrier board. Since, in the present invention, the active surface of the semiconductor chip is slightly lower than the first surface of the carrier board, it can be ensured that the opening of the carrier board is completely filled with adhesive material so as to fix the semiconductor chip therein. Moreover, thermal stress generated due to heat treatment causing cracking of the semiconductor chip can be avoided, thereby improving reliability of the product. Moreover, when the adhesive material overflows, it naturally covers a part of the active surface of the semiconductor chip, allowing the periphery of the semiconductor chip to be surrounded by a material with the same thermal expansion coefficient, so as to make the whole structure more stable and reliable.

In summary, a carrier board structure with a semiconductor chip embedded therein proposed by the present invention solves the drawbacks of the prior-art technique for a conventional circuit board with an embedded semiconductor chip, such as damage to the semiconductor chip and the popcorn effect of the circuit board, thereby improving the reliability of the product as well as simplifying the fabrication process.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A carrier board structure with a semiconductor chip embedded therein, comprising:
a carrier board having a first surface with at least one opening formed thereon and an opposing second surface;
a semiconductor chip having an active surface and an opposing inactive surface, wherein the semiconductor chip is embedded in the opening in such a way that the active surface is lower than the first surface of the carrier board; and
an adhesive material for filling a gap between the carrier board and the semiconductor chip, and for covering a part of the active surface of the semiconductor chip to fix the semiconductor chip in the opening.

2. The carrier board structure with a semiconductor chip embedded therein of claim 1, wherein the opening of the carrier board penetrates through the first and the second surfaces of the carrier board.

3. The carrier board structure with a semiconductor chip embedded therein of claim 1, wherein the opening of the carrier board penetrates through the first surface, but not the second surface.

4. The carrier board structure with a semiconductor chip embedded therein of claim 1, wherein the carrier board is selected from the group comprising of metal board, ceramic board, insulating board, and organic circuit board.

5. The carrier board structure with a semiconductor chip embedded therein of claim 4, wherein the organic circuit board is one of a printed circuit board and an IC packaging substrate.

6. The carrier board structure with a semiconductor chip embedded therein of claim 1, wherein the semiconductor chip is one of an active component and a passive component.

7. The carrier board structure with a semiconductor chip embedded therein of claim 1, wherein a plurality of electrode pads are formed on the active surface of the semiconductor chip.

8. The carrier board structure with a semiconductor chip embedded therein of claim 7, further ccomprising a circuit build-up structure formed on the first surface of the carrier board and the active surface of the semiconductor chip, wherein a plurality of conductive vias are formed in the circuit build-up structure for electrically connecting with the electrode pads of the semiconductor chip, and plurality of conductive pads are formed on a surface of the circuit build-up structure.

9. The carrier board structure with a semiconductor chip embedded therein of claim 8, wherein an insulating layer having a plurality of openings for exposing the conductive pads of the circuit build-up structure is formed on the surface of the circuit build-up structure.

10. The carrier board structure with a semiconductor chip embedded therein of claim 8, wherein the circuit build-up structure further comprises a dielectric layer, circuit layer formed on the dielectric layer, and conductive vias formed in the dielectric layer.

11. The carrier board structure with a semiconductor chip embedded therein of claim 1, wherein the adhesive material is made of a material selected from the group consisting of plastic material, resin, epoxy compound, and synthetic rubber.

12. The carrier board structure with a semiconductor chip embedded therein of claims 10, wherein the material of the dielectric layer is selected from material the same as or different from the adhesive material.
